(19) United States
(12) Patent Application Publication
(10) Pub. No.: US 2003/0135648 A1
(43) Pub. Date: Jul. 17, 2003

(54) CIM to SNMP data mapper

(76) Inventor: Dana J. Porter, Westford, MA (US)

Correspondence Address: BROMBERG & SUNSTEIN LLP, 125 SUMMER STREET, BOSTON, MA, 02110-1618, US

(21) Appl. No.: 09/981,612

(22) Filed: Oct. 16, 2001

(51) Int. Cl. G06F 15/16; G06F 15/00; G06F 7/00; H03M 7/00

(52) U.S. Cl. 709/246; 709/230; 708/204; 341/50

(57) ABSTRACT

A method for accessing SNMP-formatted management information from an SNMP agent using techniques for managing CIM-formatted management information.

### TECHNICAL FIELD

The present invention relates to methods for accessing management information on computer systems.

### BACKGROUND ART

Simple Network Management Protocol (“SNMP”) is an industry standard that models network devices in an enterprise computing environment. SNMP is a mature standard—many systems currently collect SNMP-formatted management data. An SNMP client can request SNMP data from an SNMP agent running on a system and the agent will retrieve the SNMP data and returns it to the SNMP client. Likewise, an SNMP client can request that certain variables for management data be set on the system and the SNMP agent will change these variables accordingly. SNMP is specified in RFCs 1155 and 2578, published by the Internet Society International Secretariat, 1775 Wiehle Ave., Suite 102, Reston, Va. 20190, which are incorporated herein by reference.

The data that can be retrieved or set by an SNMP agent is described in a Management Information Base (“MIB”) file or files. Each SNMP data item is associated with a unique numeric string called an Object Identifier (“OID”) which is described in the MIB together with the type of the data item. Common Information Model (“CIM”) is a more recent standard that models all elements in an enterprise computing environment. CIM allows a client to manage those elements, i.e., not just networking elements. A client can request management information data to be retrieved from or set by a CIM object manager running on a system. CIM is specified in CIM Specification v 2.2, published by the Distributed Management Task Force, 200 SW Market Street, Suite 450, Portland, Oreg. 97201, which is incorporated herein by reference.

CIM data that can be retrieved or set is described in a Managed Object Format (“MOF”) file(s). These MOF files define CIM classes, which are containers for related information, e.g., a system class would be a container of system information. A CIM class comprises CIM properties, which are attributes associated with a CIM class, e.g., one piece of information such as “system name” in the system class. A CIM qualifier is extra information to describe a CIM property. A CIM key qualifier identifies a CIM property as an index property. To retrieve a particular instance of a CIM class in the CIM model, the requestor must supply values for all the pertinent keys that uniquely identify that instance. A CIM association class is a container of associations between two CIM classes. A CIM object path object describes parameters need to access a particular CIM class or CIM class instance, i.e., a CIM object path object is a container of CIM namespace, CIM class name and optional key properties.

Current CIM protocols do not allow a CIM client to access management information that is accessible to SNMP agents, running either locally or on remote systems.

### SUMMARY OF THE INVENTION

In an embodiment of the present invention, a Common Information Model object manager (“CIMOM”) provides an application programming interface (“API”) to client applications to request or to set data associated with elements in an enterprise computing environment. Some of these elements may be network elements that respond to requests to retrieve or to set data according to SNMP. The data that can be retrieved or set by a process, called an SNMP agent, at such a network element, is described in Management Information Base (“MIB”) files. Data from the MIB file(s) is transformed into Managed Object Format (“MOF”) files by a MIB-to-MOF process. These MOF files can then be loaded with CIMOM. These MOF files contains object classes that define the information that can be requested by a CIMOM client from an SNMP-enabled network element.

CIMOM interfaces with an SNMP “provider” process that receives requests from CIMOM to access SNMP information on a network element. The SNMP provider accesses CIM objects that incorporate information necessary to form requests to SNMP agents. CIMOM forms these CIM objects from classes defined by MOF files generated by the MIB-To-MOF process. The SNMP provider prepares request messages according to SNMP formats and transmits the request messages to an SNMP agent, running either locally or on a remote system. These requests either cause data to be retrieved by the agent or cause variables to be set by the agent. The SNMP provider receives a response to the request message from the SNMP agent and maps the response into the CIM data objects. The SNMP provider then completes the request from CIMOM. CIMOM then returns the completed request to the client.

This embodiment of the invention advantageously provides access to SNMP-formatted management information on a system that has implemented CIM protocols.

### BRIEF DESCRIPTION OF THE DRAWINGS

The foregoing features of the invention will be more readily understood by reference to the following detailed description, taken with reference to the accompanying drawings, in which:

FIG. 1 is a block diagram for a portion of an enterprise computing system according to an embodiment of the invention; and

FIG. 2 is a flow chart illustrating a method of accessing SNMP data according to an embodiment of the invention.

### DETAILED DESCRIPTION OF SPECIFIC EMBODIMENTS

In an embodiment of the present invention, a MIB file is presented that specifies data that can be requested from or set by an SNMP agent running on a system, in response to an SNMP get or set message. The MIB file is transformed into a MOF file by a MIB-To-MOF process. This transformation may be effected as follows:

1. A MOF file is generated for each SNMP group or row sequence in a table defined in the MIB file. Each MOF file defines a CIM class or classes. For each MOF file generated, the MOF file name and CIM class name may be formed, for example, by combining the MIB file name and the SNMP group name or sequence name for a table row.

2. A mappingstring qualifier, containing the OID of the SNMP group or row sequence, is generated for the CIM class. A provider qualifier identifying the SNMP provider is also generated.

3. Two default properties required of all CIM classes, SystemCreationClassName and SystemName, are generated for the class. These properties are defined for CIM purposes but unused for SNMP purposes.

4. For all other CIM properties within the CIM class, a CIM mappingstring qualifier and CIM mappingtype qualifier are generated. The former contains a full numeric OID for each SNMP variable while the latter is the SNMP data type for the variable. These qualifiers are used by the SNMP provider to generate a SNMP request message. The mapping of SNMP data types to CIM data types is shown in Table 1.

5. CIM key qualifiers on properties are inserted into the CIM class to correspond to SNMP indexes into tables, i.e., to serve as the data to append to a row definition to identify the specific row desired in a table. These properties are inserted directly after the Systemcreationclassname and Systemname and are in the order specified by the index clause in the MIB file.

6. CIM property Systemname is used to obtain SNMP configuration information that can be populated and used to specify non-default SNMP connection parameters (i.e., community string, timeout, port number, etc.)

7. A CIM Association class is generated to form an association between the CIM class defined in the MOF and the Solaris_SNMPSystem class. The latter is a class containing a system name to use to obtain SNMP configuration information that can be populated and used to specify non-default SNMP connection parameters (i.e., community string, timeout, port number, etc.).

Table 2 is a sample MIB file. The file name for the MIB is “MIB_DEMO” and the group name for the SNMP group it defines is “demo.” The MIB file also contains a table row definition called “demotable.” The MIB-to-MOF process transforms this file into the MOF files shown in tables 3 and 4.

As shown in Table 2, the OID for group demo is 1.3.6.1.4.1.42.1000, which is an internet private OID for Sun Microsystems, Inc. for this group. The MIB defines three objects, “demostring,” “demointeger,” and “demooid,” with OID suffixes of .1, .2 and .3 respectively. The SNMP datatypes of these data items are “Opaque”, “Integer”, and “Object identifier” respectively.

As shown in Table 3, these three SNMP data items are used to generate CIM properties Demostring, Demointeger and DemoOID in the class SNMP_DEMO_MIBDemo, which is contained in a MOF file of the same name. A mappingstring for each property contains the OID for the data item. The mappingtype for the property contains the SNMP datatype of the data item. The class has a provider qualifier that identifies the SNMP provider process as “com.sun.wbem.snmpprovider.SNMPProvider.”

Table 4 shows the second MOF file that is generated from the MIB in Table 2. This MOF file defines a row of the table “demotable.” As shown in Table 2, the OID for group “demo” is 1.3.6.1.4.1.42.1000.10.1, which is an internet private OID for Sun Microsystems, Inc. for this row sequence. The MIB defines four objects, “demoentryindex,” “demoentrystring,” “demoentryinteger,” and “demoentryoid,” with OID suffixes of .1, .2, .3 and .4 respectively. The SNMP datatypes of these data items are “Int”, “String” “Integer”, and “SNMPOID” respectively. As shown in Table 4, these four SNMP data items are used to generate CIM properties Demoentryindex, Demoentrystring, Demoentryinteger and DemoentryOID in the class SNMP_DEMO_MIBDemoEntry, which is contained in a MOF file of the same name. A mappingstring for each property contains the OID for the data item. The mappingtype for the property contains the SNMP datatype of the data item. The class has a provider qualifier that identifies the SNMP provider process as “com.sun.wbem.snmpprovider.SNMPProvider.”

TABLE 1
SNMP to CIM Data Type Mapping

| SNMP Datatype | CIM Datatype |
|---|---|
| Integer | Sint32 |
| Octet String | String |
| Object Identifier | String |
| IpAddress | String |
| Counter | Uint32 |
| Gauge | Uint32 |
| Timeticks | Uint32 |
| Opaque | Sint[] |
| Displaystring | String |
| Networkaddress | String |
| Counter32 | Uint32 |
| Counter64 | Uint64 |
| Integer32 | Sint32 |
| Gauge32 | Uint32 |
| Unsigned32 | Uint32 |
| Truthvalue | Sint32 |
| Bits | String |

TABLE 2
Sample MIB File

DEMO-MIB DEFINITIONS ::= BEGIN
IMPORTS

OBJECT-TYPE, Counter32, Gauge32

FROM SNMPv2-SMI

DisplayString, TimeStamp

FROM SNMPv2-TC;

| | |
|---|---|
| mib-2 | OBJECT IDENTIFIER ::= {mgmt 1} |

| | |
|---|---|
| sun | OBJECT IDENTIFIER ::= {enterprises 42} |
| demo | OBJECT IDENTIFIER ::= {sun 1000} |

--
// Some objects
//

demoString OBJECT-TYPE

SYNTAX Opaque
MAX-ACCESS read-write
STATUS current
DESCRIPTION

“A read-write object of type String.”

::= {demo 1}

demoInteger OBJECT-TYPE

SYNTAX INTEGER {

up(1),
down(2)

}
MAX-ACCESS read-write
STATUS current
DESCRIPTION

“A read-write object of type Integer.”

::= {demo 2}

demoOid OBJECT-TYPE

SYNTAX OBJECT IDENTIFIER
MAX-ACCESS read-write
STATUS current
DESCRIPTION

“A read-write object of type Oid.”

::={demo 3}

//
//A table composed of some columns
//

demoTable OBJECT-TYPE

SYNTAX SEQUENCE OF DemoEntry
MAX-ACCESS not-accessible
STATUS current
DESCRIPTION

“A table.”

::= {demo 10}

demoEntry OBJECT-TYPE

SYNTAX DemoEntry
MAX-ACCESS not-accessible
STATUS current
DESCRIPTION

“An entry in the table demoTable.”

INDEX {demoEntryIndex}
::= {demoTable 1}

DemoEntry ::= SEQUENCE {

demoEntryIndex

INTEGER,

demoEntryString

DisplayString,

demoEntryInteger

INTEGER,

demoEntryOid

OBJECT IDENTIFIER

}
demoEntryIndex OBJECT-TYPE

SYNTAX INTEGER (1..2147483647)
MAX-ACCESS not-accessible
STATUS current
DESCRIPTION

“An index to uniquely identify the entry.”

::= {demoEntry 1}

demoEntryString OBJECT-TYPE

SYNTAX DisplayString
MAX-ACCESS read-write
STATUS current
DESCRIPTION

“A read-write column of type String.”

::= {demoEntry 2}

demoEntryInteger OBJECT-TYPE

SYNTAX INTEGER {

up(1),
down(2)

}
MAX-ACCESS read-write
STATUS current
DESCRIPTION

“A read-write column of type Integer.”

::= {demoEntry 3}

demoEntryOid OBJECT-TYPE

SYNTAX OBJECT IDENTIFIER
MAX-ACCESS read-write
STATUS current
DESCRIPTION

“A read-write column of type Oid.”

::= {demoEntry 4}

END

TABLE 3

//==================================
// Title: SNMP_DEMO_MIBDemo
// Note: MOF file Generated from: DEMO_MIB file
//======================================
#pragma namespace(“root/snmp”)
[Provider(“com.sun.wbem.snmpprovider.SnmpProvider”),

Mappingstring(“snmp:1.3.6.1.4.1.42.1000”)
]

class SNMP_DEMO_MIBDemo
{

[Key,
Propagated(“Solaris_SNMPSystem.CreationClassName”)
]
string SystemCreationClassName;

[Key,

Propagated(“Solaris_SNMPSystem.Name”)
]
string SystemName;

[Mappingstring(“snmp:1.3.6.1.4.1.42.1000.3”),

MappingType(“SnmpOid”),
Write(true)
]
string DemoOid;

[Mappingstring(“snmp:1.3.6.1.4.1.42.1000.2”),

MappingType(“SnmpInt”),
Write(true),
ValueMap{“2”, “1”},
Values{“down”, “up”}
]
sint32 DemoInteger;

[Mappingstring(“snmp:1.3.6.1.4.1.42.1000.1”),

MappingType(“SnmpOpaque”),
Write(true)
]
sint8 DemoString[];

};
[Association,

Provider(“com.sun.wbem.snmpprovider.SnmpProvider”)
]

class SNMP_DEMO_MIBDemo_SNMP_System
{

Solaris_SNMPSystem REF SNMPSystem;
[Weak
]
SNMP_DEMO_MIBDemo REF SNMPMib;

};

TABLE 4
MOF File for Table

// ==============================================
=
// Title: SNMP_DEMO_MIBDemoEntry
// Generated from: DEMO_MIB
// Warning: Do not re-order Key-qualified properties.
// ==============================================
=
#pragma namespace(“root/snmp”)

[Provider(“com.sun.wbem.snmpprovider.SnmpProvider”),

Mappingstring(“snmp:1.3.6.1.4.1.42.1000.10.1”)

]

class SNMP_DEMO_MIBDemoEntry
{

[Key,

Propagated(“Solaris_SNMPSystem.CreationClassName”)

]
string SystemCreationClassName;
[Key,

Propagated(“Solaris_SNMPSystem.Name”)

]
string SystemName;
[Key,

Mappingstring(“snmp:1.3.6.1.4.1.42.1000.10.1.1”),
MappingType(“SnmpInt”),
Write(false)

]
sint32 DemoEntryIndex;
[Mappingstring(“snmp:1.3.6.1.4.1.42.1000.10.1.3”),

MappingType(“SnmpInt”),
Write(true),
ValueMap{“2”, “1”},
Values{“down”, “up”}

]
sint32 DemoEntryInteger;
[Mappingstring(“snmp:1.3.6.1.4.1.42.1000.10.1.2”),

MappingType(“SnmpString”),
Write(true)

]
string DemoEntryString;
[Mappingstring(“snmp:1.3.6.1.4.1.42.1000.10.1.4”),
MappingType(“SnmpOid”),
Write(true)
]
string DemoEntryOid;

};

[Association,
Provider(“com.sun.wbem.snmpprovider.SnmpProvider”)
]

class SNMP_DEMO_MIBDemoEntrySNMP_System
{

Solaris_SNMPSystem REF SNMPSystem;
[Weak
]
SNMP_DEMO_MIBDemoEntry REF SNMPMib;

};

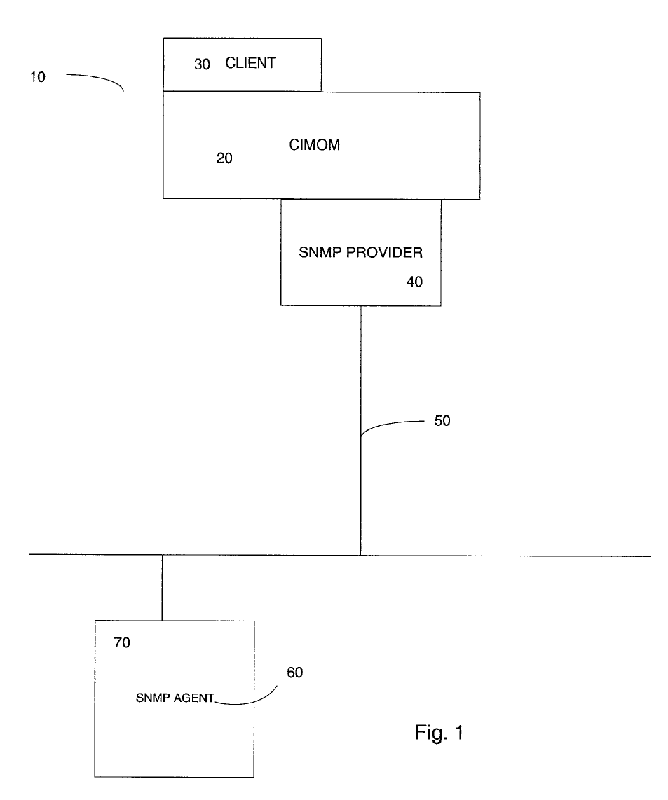

FIG. 1 is a block diagram of elements in an enterprise computing system according to an embodiment of the present invention. A computing system 10 executes a CIMOM process 20. CIMOM 20 receives requests for SNMP management information from a client application 30. CIMOM calls an SNMP provider 40. The SNMP provider communicates with an SNMP agent process 60, running on a remote system 70 over a network 50. The SNMP agent 60 may also be local to system 10.

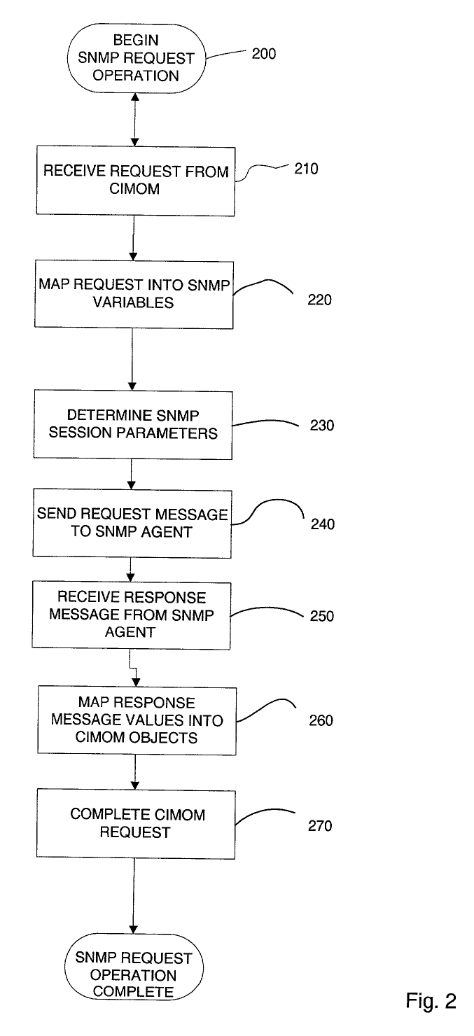

FIG. 2 is a flow diagram showing a method for a client application to access SNMP information from an SNMP agent using CIM calling conventions, according to an embodiment of the present invention. First, the SNMP provider receives 210 an SNMP data access request from CIMOM, identifying a CIM class whose objects describe data to either be received from an SNMP agent or set by an SNMP agent. The CIM class name includes the group or row name to be accessed.

Next, the SNMP provider reads each property in the CIM class instance whose name matches the class identified by CIMOM in the request. Each property in the CIM class has associated qualifiers that contains the OID of an SNMP variable together with its SNMP type, as described above. The request includes the system name of the system where the SNMP agent is running, if the agent is remote, and whether the request is to get information, to set information or to enumerate (list) the rows of a table. The SNMP provider processes each property in the CIM class instance. The SNMP provider maps 220 the CIM datatypes into SNMP datatypes and forms a SNMP request message that includes the OIDs and values, if variables are to be set, corresponding to the group data items or table data items to be accessed. The OID is augmented by an index obtained from key qualified properties on a CIM object path object. If no keys are specified in the object path object, a “.0” is added to the OID. Otherwise the key values from the object path object are converted to SNMP data types and appended to the index.

The SNMP provider determines 230 the session parameters to be used in communicating with the SNMP agent. The SNMP provider may receive the system name on which the SNMP agent to be accessed is running, either from a CIM object path object for a get or a set operation or the CIM association object, for an enumerate instance operation. The SNMP provider then requests a configuration class instance from CIMOM that matches the group name and system name. If an instance matching these names is found, SNMP session parameters (e.g, port number, timeout values, etc.) defined by this instance are accessed. If no instance is found, the SNMP provider requests a configuration class instance that matches the system name. If an instance matching this name is found, SNMP session parameters from this instance are used. Otherwise, default session parameters are used to establish the session with the SNMP agent, which agent will be local to the system on which the SNMP provider is running.

Next the SNMP provider sends 240 a request message to the SNMP agent, using the appropriate session parameters.

The SNMP provider receives 250 the response message from the SNMP agent and correlates the response data by using the OIDs returned with each variable value in the response message. Each value returned is converted 260 as necessary into the CIM datatype specified in the CIM class for the request and mapped into the CIM objects.

The SNMP provider then completes the request 270 by returning the CIM data object to the CIM object manager.

It should be noted that the flow diagrams are used herein to demonstrate various aspects of the invention, and should not be construed to limit the present invention to any particular logic flow or logic implementation. The described logic may be partitioned into different logic blocks (e.g., programs, modules, functions, or subroutines) without changing the overall results or otherwise departing from the true scope of the invention. Oftentimes, logic elements may be added, modified, omitted, performed in a different order, or implemented using different logic constructs (e.g., logic gates, looping primitives, conditional logic, and other logic constructs) without changing the overall results or otherwise departing from the true scope of the invention.

The present invention may be embodied in many different forms, including, but in no way limited to, computer program logic for use with a processor (e.g., a microprocessor, microcontroller, digital signal processor, or general purpose computer), programmable logic for use with a programmable logic device (e.g., a Field Programmable Gate Array (FPGA) or other PLD), discrete components, integrated circuitry (e.g., an Application Specific Integrated Circuit (ASIC)), or any other means including any combination thereof.

Computer program logic implementing all or part of the functionality previously described herein may be embodied in various forms, including, but in no way limited to, a source code form, a computer executable form, and various intermediate forms (e.g., forms generated by an assembler, compiler, linker, or locator.) Source code may include a series of computer program instructions implemented in any of various programming languages (e.g., an object code, an assembly language, or a high-level language such as Fortran, C, C++, JAVA, or HTML) for use with various operating systems or operating environments. The source code may define and use various data structures and communication messages. The source code may be in a computer executable form (e.g., via an interpreter), or the source code may be converted (e.g., via a translator, assembler, or compiler) into a computer executable form.

The computer program may be fixed in any form (e.g., source code form, computer executable form, or an intermediate form) either permanently or transitorily in a tangible storage medium, such as a semiconductor memory device (e.g., a RAM, ROM, PROM, EEPROM, or Flash-Programmable RAM), a magnetic memory device (e.g., a diskette or fixed disk), an optical memory device (e.g., a CD-ROM), a PC card (e.g., PCMCIA card), or other memory device. The computer program may be fixed in any form in a signal that is transmittable to a computer using any of various communication technologies, including, but in no way limited to, analog technologies, digital technologies, optical technologies, wireless technologies, networking technologies, and internetworking technologies. The computer program may be distributed in any form as a removable storage medium with accompanying printed or electronic documentation (e.g., shrink wrapped software or a magnetic tape), preloaded with a computer system (e.g., on system ROM or fixed disk), or distributed from a server or electronic bulletin board over the communication system (e.g., the Internet or World Wide Web.)

Hardware logic (including programmable logic for use with a programmable logic device) implementing all or part of the functionality previously described herein may be designed using traditional manual methods, or may be designed, captured, simulated, or documented electronically using various tools, such as Computer Aided Design (CAD), a hardware description language (e.g., VHDL or AHDL), or a PLD programming language (e.g., PALASM, ABEL, or CUPL.)

The present invention may be embodied in other specific forms without departing from the true scope of the invention. The described embodiments are to be considered in all respects only as illustrative and not restrictive.

What is claimed is:

1. A method for accessing management information in CIM-format transferred by an agent in SNMP-format, the method comprising:
receiving a data request from a CIM object manager including CIM data objects;
mapping the data request into an SNMP request;
transmitting the request to the SNMP agent; and
receiving a response to the SNMP request message from the SNMP agent.

2. A method according to claim 1, the method further comprising:
reading configuration information including SNMP session attributes, wherein transmitting requests to the SNMP agent and receiving responses from the SNMP agent is according to the session attributes.

3. A method according to claim 1, the method further comprising:
mapping response data into the CIM data objects; and
completing the data request including returning the CIM data objects to the CIM object manager.

4. A method for generating a MOF file from a MIB file, the MIB file including at least one SNMP variable, comprising:
generating a MOF file for at least one of a group and a row sequence specified in the MIB file, the MOF file including an object class; and
generating a property and property qualifiers including an OID and SNMP datatype for each SNMP variable in the MIB file for inclusion in the MOF file.

5. A computer program product for use on a computer system for accessing management information in CIM-format transferred by an agent in SNMP-format, the computer program product comprising a computer usable medium having computer readable program code thereon, the computer readable program code including program code for:
receiving a data request from a CIM object manager including CIM data objects;
mapping the data request into an SNMP request;
transmitting the request to the SNMP agent; and
receiving a response to the SNMP request message from the SNMP agent.

6. A computer program product for generating a MOF file from a MIB file, the MIB file including at least one SNMP variable, the computer program product comprising a computer usable medium having computer readable program code thereon, the computer readable program code including program code for:
generating a MOF file for at least one of a group and a row sequence specified in the MIB file, the MOF file including an object class; and
generating a property and property qualifiers including an OID and SNMP datatype for each SNMP variable for inclusion in the MOF file.
